(19) United States
(12) Patent Application Publication
(10) Pub. No.: US 2014/0097539 A1
(43) Pub. Date: Apr. 10, 2014

(54) TECHNIQUE FOR UNIFORM CMP

(71) Applicants: STMicroelectronics, Inc., Coppell, TX (US); International Business Machines Corporation, Armonk, NY (US)

(72) Inventors: John H. Zhang, Fishkill, NY (US); Wei-Tsu Tseng, Hopewell Junction, NY (US); Tien-Jen Cheng, Bedford, NY (US); Laertis Economikos, Wappingers Falls, NY (US)

(21) Appl. No.: 13/928,084

(22) Filed: Jun. 26, 2013

Related U.S. Application Data
(60) Provisional application No. 61/711,002, filed on Oct. 8, 2012.

(51) Int. Cl. H01L 21/768; H01L 23/522

(52) U.S. Cl. CPC H01L 21/7684; H01L 23/522
USPC 257/752; 438/672; 438/692

(57) ABSTRACT

Pitch-dependent dishing and erosion following CMP treatment of copper features is quantitatively assessed by atomic force microscopy (AFM) and transmission electron microscopy (TEM). A new sequence of processing steps presented herein is used to prevent dishing and to reduce significantly the local pitch- and pattern density-induced CMP non-uniformity for copper metal lines having widths and spacing in the range of about 32-128 nm. The new process includes a partial copper deposition step followed by deposition of a silicon carbide/nitride (SiCₓN_{y}) blocking layer. A multi-step CMP process planarizes areas of the resulting irregular surface that have narrow features, while the blocking layer protects areas that have wide features.

### RELATED APPLICATION

This patent application claims benefit under 35 U.S.C. §119(e) of U.S. Provisional Patent Application No. 61/711,002, filed on Oct. 8, 2012, which is hereby incorporated by reference in its entirety.

### BACKGROUND

1. Technical Field

The present disclosure relates to the use of chemical-mechanical planarization (CMP) of 10-100 nanometer-sized integrated circuit features and, in particular, to techniques for achieving feature-scale uniformity within a die.

2. Description of the Related Art

CMP is a polishing technique used in the semiconductor industry to planarize (i.e., make flat) the surface of a semiconductor wafer at various times during an integrated circuit fabrication process. Typically, it is desirable to planarize the wafer surface after completing deposition and patterning of a layer, before proceeding to deposit a next layer of material. If planarization is omitted, the topography of the un-planarized surface can be transferred to, or accentuated in, subsequent layers. Such topography effects are more likely to occur if materials used in subsequent layers have poor ability to fill surface recesses.

A CMP process typically entails polishing the wafer surface using a rotating pad and a slurry made from various chemicals and abrasive particulates, so that both chemical and physical removal mechanisms contribute to the planarization. Depending on the materials and the features being polished, the CMP process may gouge the surface, causing CMP-induced topography and thereby degrading the surface uniformity. Such gouging of the surface is sometimes referred to as “dishing.” If local erosion is too great, the CMP process used during subsequent layers may not effectively remove material (e.g., metal) from recessed areas. Puddle defects in which residual metal is left behind in the recessed areas can cause short circuits.

Non-uniform topography may occur on any of three different scales: wafer scale, die scale, and feature scale. Wafer-scale topography variation results from radial variation in the CMP process, from the center of a semiconductor wafer to the edge of the wafer. Wafer-scale topography variation can be addressed by adjusting CMP equipment parameters or materials used in the CMP process itself. Die-scale variation depends primarily on the pattern density of circuit features, which is largely determined by circuit mask designs. Wafer-scale and die-scale variation can also be compensated for in a lithography scanner through focus-level adjustment by measuring wafer surface heights before each exposure. Today, optical or mechanical detection of long-range wafer surface height variation and focus adjustment is possible in most advanced lithography systems.

Feature-scale topography variation, however, is dependent on individual line widths, line spaces, or feature shapes, and cannot be compensated for in a lithography step because the variation is within an individual exposure field. Thus, non-uniform topography at the feature level poses a critical challenge for CMP process development as feature sizes continue to shrink. Reducing feature-scale post-CMP non-uniformities for advanced technology generations is therefore of considerable interest to semiconductor technologists.

### BRIEF SUMMARY

A new sequence of processing steps presented herein is used to prevent dishing and to reduce significantly the local pitch- and pattern density-induced CMP non-uniformity for copper metal lines having widths and spacing in the range of about 32-128 nm. While an integrated circuit is being made, a non-uniform pattern of trenches is created in a high-k inter-layer dielectric. Copper metal lines are inlaid by partially filling the trenches, with the result that the thickness of the copper varies according to changes in width, depth of trenches, as well as the density of the trenches in the non-uniform pattern. Next, a silicon carbide/nitride (SiCₓN_{y}) blocking layer is blanket deposited. A multi-step CMP process then planarizes the entire wafer with the result that areas of the planarized irregular surface that have narrow features will have the blocking layer removed, while the blocking layer protects trenches that have wide features.

### BRIEF DESCRIPTION OF THE SEVERAL VIEWS OF THE DRAWINGS

In the drawings, identical reference numbers identify similar elements. The sizes and relative positions of elements in the drawings are not necessarily drawn to scale.

FIG. 1 is a post-CMP cross-sectional diagram of metal nanowires adjacent to a metal field inlaid in a dielectric material, in which the metal field exhibits severe erosion from a prior art CMP process.

FIG. 2 is a high-level process flow diagram showing a sequence of process steps in a uniform CMP method that can be used to effectively planarize non-uniform topography by protecting the metal fields.

FIG. 3A is a detailed process flow diagram showing a sequence of process steps that can be used to create narrow features adjacent to wide features.

FIGS. 3B-3D are cross-sectional views of profiles formed by each of the process steps shown FIG. 3A.

FIG. 4A is a detailed process flow diagram showing a sequence of process steps that can be used to effectively planarize non-uniform topography by protecting the metal fields.

FIGS. 4B-4D are cross-sectional views of profiles formed by each of the process steps shown FIG. 4A.

FIG. 5 is a plot of a set of atomic force microscopy measurement data comparing surface planarity following a traditional CMP process and a new CMP process used to treat copper nanowires placed next to a field of copper, as shown in FIG. 1.

### DETAILED DESCRIPTION

In the following description, certain specific details are set forth in order to provide a thorough understanding of various aspects of the disclosed subject matter. However, the disclosed subject matter may be practiced without these specific details. In some instances, well-known structures and methods of semiconductor processing comprising embodiments of the subject matter disclosed herein have not been described in detail to avoid obscuring the descriptions of other aspects of the present disclosure.

Unless the context requires otherwise, throughout the specification and claims that follow, the word “comprise” and variations thereof, such as “comprises” and “comprising” are to be construed in an open, inclusive sense, that is, as “including, but not limited to.”

Reference throughout the specification to “one embodiment” or “an embodiment” means that a particular feature, structure, or characteristic described in connection with the embodiment is included in at least one embodiment. Thus, the appearance of the phrases “in one embodiment” or “in an embodiment” in various places throughout the specification are not necessarily all referring to the same aspect. Furthermore, the particular features, structures, or characteristics may be combined in any suitable manner in one or more aspects of the present disclosure.

Reference throughout the specification to integrated circuits is generally intended to include integrated circuit components built on semiconducting substrates, whether or not the components are coupled together into a circuit or able to be interconnected. Throughout the specification, the term “layer” is used in its broadest sense to include a thin film, a cap, or the like.

Reference throughout the specification to conventional thin film deposition techniques for depositing silicon nitride, silicon dioxide, metals, or similar materials include such processes as chemical vapor deposition (CVD), low-pressure chemical vapor deposition (LPCVD), metal organic chemical vapor deposition (MOCVD), plasma-enhanced chemical vapor deposition (PECVD), plasma vapor deposition (PVD), atomic layer deposition (ALD), molecular beam epitaxy (MBE), electroplating, electro-less plating, and the like. Specific embodiments are described herein with reference to examples of such processes. However, the present disclosure and the reference to certain deposition techniques should not be limited to those described. For example, in some circumstances, a description that references CVD may alternatively be done using PVD, or a description that specifies electroplating may alternatively be accomplished using electro-less plating. Furthermore, reference to conventional techniques of thin film formation may include growing a film in-situ. For example, in some embodiments, controlled growth of an oxide to a desired thickness can be achieved by exposing a silicon surface to oxygen gas or to moisture in a heated chamber.

Reference throughout the specification to conventional photolithography techniques, known in the art of semiconductor fabrication for patterning various thin films, includes a spin-expose-develop process sequence typically followed by an etch process. Alternatively or additionally, photoresist can also be used to pattern a hard mask (e.g., a silicon nitride hard mask), which, in turn, can be used to pattern an underlying film.

Reference throughout the specification to conventional etching techniques known in the art of semiconductor fabrication for selective removal of polysilicon, silicon nitride, silicon dioxide, metals, photoresist, polyimide, or similar materials includes such processes as wet chemical etching, reactive ion (plasma) etching (RIE), washing, wet cleaning, pre-cleaning, spray cleaning, chemical-mechanical planarization (CMP) and the like. Specific embodiments are described herein with reference to examples of such processes. However, the present disclosure and the reference to certain deposition techniques should not be limited to those described. In some instances, two such techniques may be interchangeable. For example, stripping photoresist may entail immersing a sample in a wet chemical bath or, alternatively, spraying wet chemicals directly onto the sample.

Specific embodiments are described herein with reference to planarized metal interconnect structures that have been produced; however, the present disclosure and the reference to certain materials, dimensions, and the details and ordering of processing steps are exemplary and should not be limited to those shown. The terms “planarize” and “polish” are used synonymously throughout the specification.

In the figures, identical reference numbers identify similar features or elements. The sizes and relative positions of the features in the figures are not necessarily drawn to scale.

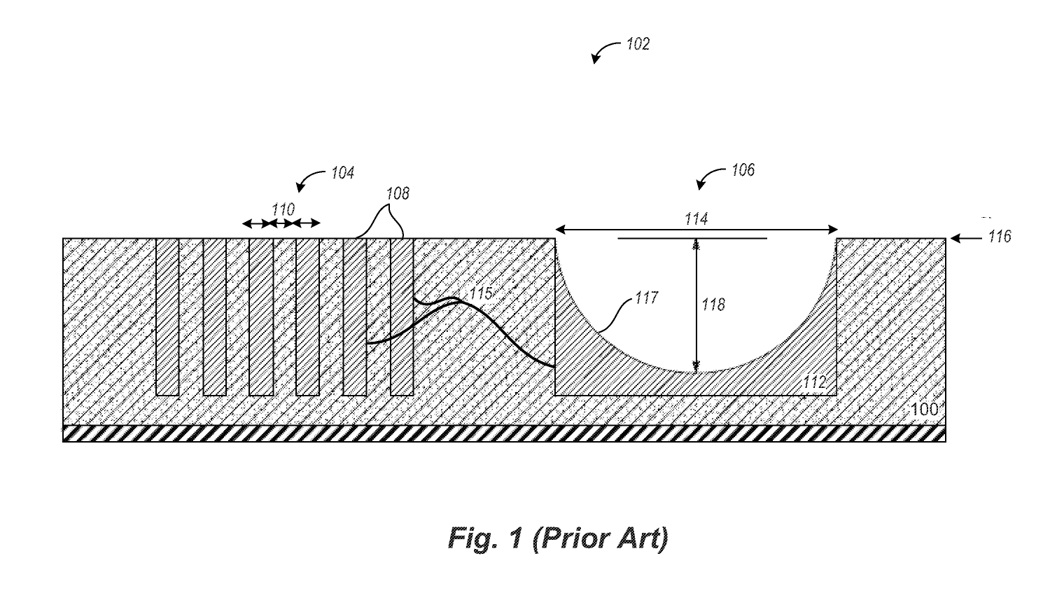

FIG. 1 shows a dielectric layer 100 in which integrated circuit features have been formed that exhibit a non-uniform surface pattern 102. In one embodiment, the non-uniform surface pattern 102 includes a densely patterned region of narrow inlaid features 104 adjacent to a wide inlaid feature 106. The narrow inlaid features 104 may be metal nanowires 108 having nanowire widths and spacings 110 in the range of, for example, 10-20 nm, while the wide inlaid feature 106 may be a metal field 112 having a metal field width 114 in the range of about 100-300 nm, or about ten times wider than the narrow inlaid features 104. Alternatively, the metal field width can also be much larger, for example, tens or hundreds of microns wide. Such metal features are typically inlaid according to a damascene process in which trenches 115 are etched into a dielectric layer 100 (e.g., an inter-layer dielectric (ILD)) and subsequently filled with metal. The metal nanowires 108 may exhibit a surface pattern that is locally uniform. However, the disparity between the small dimensions of the metal nanowires 108 compared with the large dimension of the metal field 112 constitutes the overall non-uniform surface pattern 102.

The non-uniform surface pattern 102 shown in FIG. 1 results in a non-planar surface 116 following a conventional metal CMP process performed according to the prior art. Although the narrow inlaid features 104 shown in FIG. 1 have been successfully planarized (made flat), the wide inlaid feature 106 has experienced severe dishing, resulting in a deep gouge 117 that extends downward from the surface into the metal field 112 by a gouge depth 118. Such difficulty in achieving uniform planarization of non-uniform surface patterns 102 is a known problem in the art of integrated circuit fabrication. Local uniformity specifications generally are difficult to meet simultaneously for both narrow and wide features. One difficulty is that the planarization process may be constrained by limitations of the etch chemistry and the polishing equipment. For example, equipment settings for polish pad pressure, rotation speed, and the like, that are effective in polishing the narrow features precisely, are not equally effective in polishing the wide features, and vice versa. Additionally or alternatively, material that is polished off or otherwise ejected from the narrow inlaid features 104 can become trapped in the deep gouges 117, forming surface defects. Such surface defects can leave the surface at a later time in the process, and land on neighboring circuit features. If such surface defects are metallic, they can cause short circuits.

Although, in the example shown, the inlaid features are made of metal, problems associated with polishing non-uniform surface patterns 102 are not necessarily limited to the materials shown in the examples herein. Likewise, solutions presented herein for processing metal features of disparate sizes can be generally applied to similarly disparate features made of other materials that may be inlaid in other substrates 100.

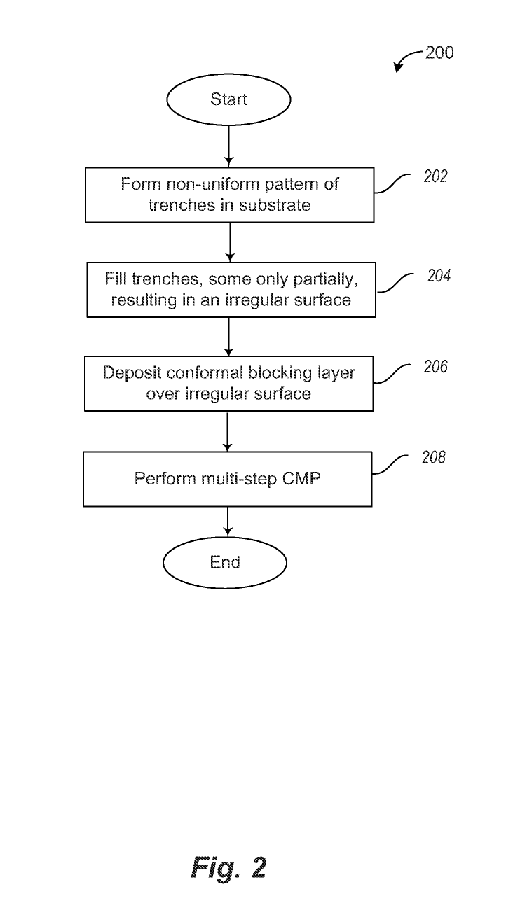

FIG. 2 shows steps in a high level uniform CMP method 200 for preventing such deep gouges 117, according to one embodiment presented herein. The uniform CMP method 200 is, by design, independent of pattern density, and thus can be used to circumvent limitations inherent in the polishing process, as described above.

At 202, the non-uniform surface pattern 102 of trenches 115 is formed in a substrate 125.

At 204, metal is blanket deposited on the surface, a deposition process (e.g., CVD or PVD) in which the metal over-fills the narrow trenches but only partially fills the wide trenches. Such a variation in metal thickness thus forms an irregular surface.

At 206, the irregular surface is covered with a blocking layer.

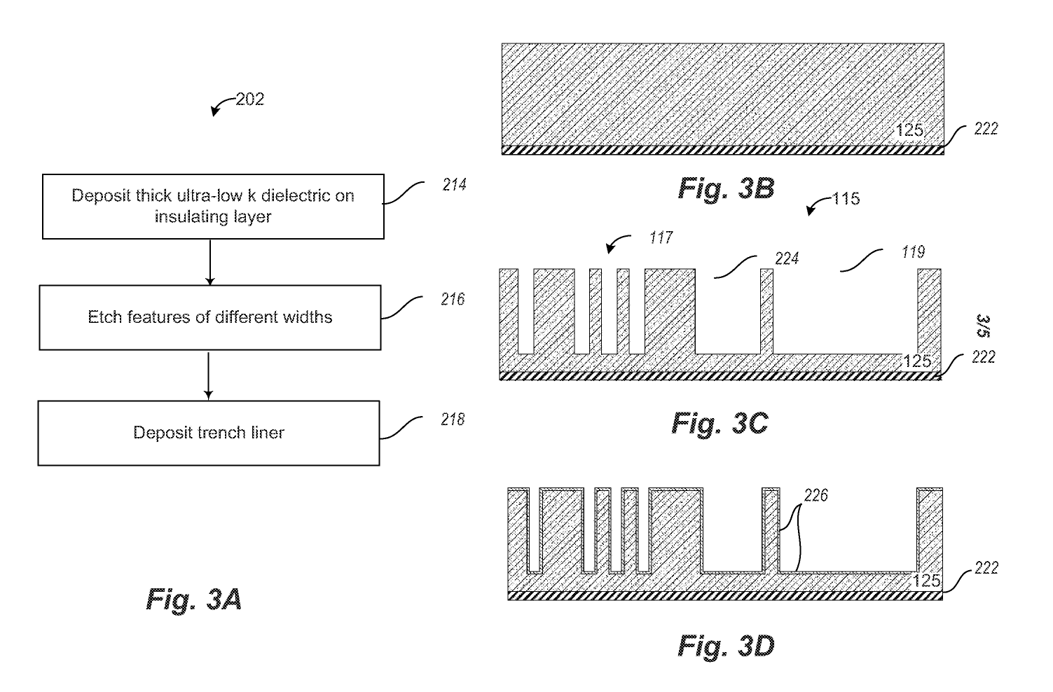

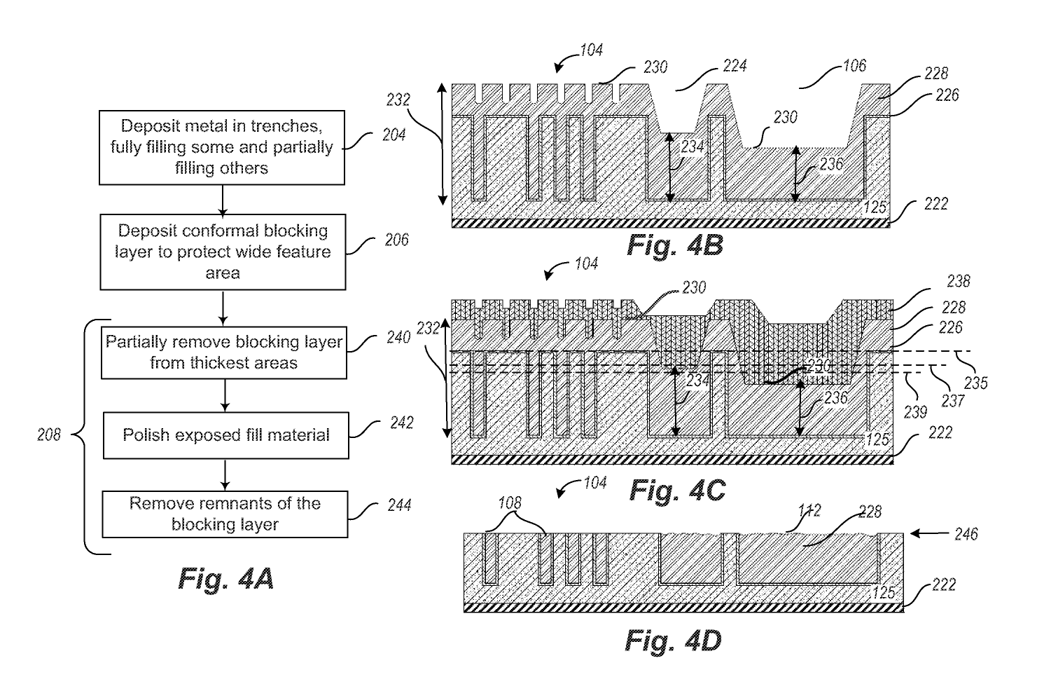

At 208, a multi-step polishing process is performed. Details of the uniform CMP method 200 are presented below, with reference to FIGS. 3A-4D.

FIGS. 3A-3D describe and show one example that results in the formation of the non-uniform surface pattern 102 at step 202. Such a non-uniform pattern can be formed in a variety of ways. Shown in FIG. 3B is an example of the starting substrate 125 which has been formed over a base layer 222. The substrate 125 can be any layer in which a highly irregular surface will be formed during the semiconductor manufacturing process. In one embodiment, the substrate 125 is an inter-metal dielectric layer such as a low-k dielectric. Such an inter-metal dielectric layer may be between metals 2 and 3, metals 3 and 4, or other metal layers. In other embodiments, substrate 125 is the combined set of layers before their first metal is formed, which includes the monocrystalline semiconductor substrate which has been overlaid with multiple layers of nitrides, gate electrodes, either composed of polysilicon or metal, sidewall spacers, contact openings, or other features of greatly different heights which are commonly formed before the first metal layer. Thus, the word “substrate” as used herein is in the broad sense of a layer of material in which subsequent processing takes place.

At 214, the substrate 125 is formed as a thick ultra-low-k (ULK) dielectric on a support layer 222. In the embodiment shown, the ULK dielectric desirably has a dielectric constant, k, in the range of about 2.0-3.0 and a thickness target of about 250 nm. The support layer 222 can be made of, for example, silicon carbide-nitride SiCₓN_{y} having a thickness of about 10-20 nm.

At 216, trenches 115 are patterned in the ULK dielectric substrate 15 by conventional lithography and reactive ion etching (RIE) processes. The irregular surface features may also be formed by depositing and etching to create non-uniform layers of significantly different heights, for example gates formed over a substrate, sidewall spacers adjacent the gates, gate electrodes overlying the gates, and further insulation layers overlying such gate electrodes; all of which are adjacent to openings to a silicon semiconductor substrate, which is another technique by which surface structures having very different heights may be formed. Patterning the ULK generally produces the narrow trenches 117, wide trenches 119, and intermediate width trenches 229, in close proximity to one another within a common die. In one embodiment, the depth of the trenches 115 is in the range of about 100-200 nm so that the narrow trenches 117 have a high aspect ratio (e.g., in the range of about 5:1 to about 10:1) that substantially exceeds the desired aspect ratio of adjacent structures (e.g., about 3:1).

At 218, a conformal, thin trench liner 226 is deposited in the trenches 115. The trench liner 226 forms a barrier between the ULK material and the trench fill material to be deposited next. The trench liner 226 can be made of tantalum nitride (TaN), for example, having a representative thickness of a few nm. Other material choices for the trench liner 226 can include titanium or titanium nitride (TiN).

FIGS. 4A-4C describe and show details of the steps 204-208 of the uniform CMP method 200.

At step 204, the trenches 115 are at least partially filled with a trench fill material 228 (FIG. 4B). The trench fill material 228 in the embodiment shown is desirably a metal suitable for use as a nanowire interconnect material. Such metals include, for example, copper, aluminum, tungsten, silver, gold, titanium, platinum, tantalum, or combinations thereof. Combinations of such metals include layered metal stacks or alloys. The trench fill material 228 tends to fill up the narrow trenches 117 first resulting in an over-fill, while the intermediate width features 224 and the wide features 119 remain only partially filled (under-fill). Thus, the trenches, after metal deposition, exhibit an irregular surface 230 having various thicknesses, 232, 234, and 236, corresponding to different widths that characterize the respective narrow features 117, intermediate width features 224, and wide features 119, respectively. Thus, the thickest areas, namely the tallest metal layers, of the irregular surface 230 correspond to the patterned regions having the narrowest features, and the thinnest areas of the irregular surface 230 correspond to the patterned areas having the widest features. The trench fill process can be a plasma deposition process such as chemical vapor deposition (CVD) or plasma vapor deposition (PVD). Alternatively, the trench fill process can be a plating process such as electroplating or electro-less plating. The filling process is desirably targeted to achieve at least a desired thickness 236 of the wide inlaid features 106. The deposition process of the metal is preferably conformal to ensure that all the features of the various trenches are completely filled. Even though the deposition is preferably conformal, because of the variations in the depths of the trenches and the great disparity in height between adjacent features, the deposition may not be fully conformal, and may be thicker on bottom surfaces than on side surfaces. This may result in further emphasizing the differences in height of the various surface features, further increasing the unevenness and irregularity of the uppermost surface.

At step 206, a blocking layer 238 is deposited over the irregular surface 230 to protect the wide inlaid features 106. The blocking layer 238 can be formed either as a conformal deposition layer or as a non-conformal layer. Even formed as a non-conformal, filling layer, often called a planarizing layer in the art, it will still have some non-uniform features and variations in height because of the great difference in the height of the irregular surface features of the uppermost surfaces of the uppermost surface 230. In one embodiment, the blocking layer is an insulating material that is substantially conformal with the underlying trench fill topography. In one embodiment, composition of the blocking layer 238 is a nitride film such as a silicon carbide-nitride (SiCₓN_{y}) having a thickness within the range within the range of about 50-100 nm. Other insulating silicon nitride compositions can also be used, as well as other insulating materials that deposit substantially conformally.

At step 208, a multi-step CMP process is performed in which exposed metal features are removed by the CMP etching down to almost the level 236 of the metal layer 228. In one embodiment, a three-step planarization process can be carried out as follows:

At 240, the blocking layer 238 is removed from the substrate 125 irregular surface 230 sufficient to remove the top part of substrate 125, to expose the nanowires 108. The CMP process used to remove the blocking layer 238 can include a slurry made from silica and hydrogen peroxide (H₂O₂), and use of a soft polish pad. Meanwhile, the metal fields 228 remain covered by the blocking layer 238 where it has not yet been removed.

At 242, the exposed fill material 228 is polished overlying the narrow inlaid features 104. Such polishing may also remove an upper portion of the nanowires 108. Because the metal fields 228 are protected over trenches 119 and 224 by the blocking layer 238, at these wide locations the metal layer 228 remains unaffected and therefore dishing is prevented of the metal layer itself.

At 244, a touch CMP process is performed to gently remove remnants of the blocking layer 238 from the wide inlaid features 224 and 119. The touch CMP process can be a brief surface polish in which the polish pad rotation speed and pressure are set to relatively low values to remove residual amounts of material while limiting the degree of surface abrasion. Alternatively, a touch clean can be substituted for the touch CMP process. The touch clean can use, for example, a wet clean chemistry that includes hydrofluoric acid (HF) diluted with de-ionized water (DI) in a 1000:1 ratio (DI:HF). Alternatively, the chemistry of the etch slurry in the CMP etch may be changed to be less aggressive in etching the blocking layer 238, or, in some cases, the metal layer 228. For example, the first etch chemistry of the first CMP etch as carried out in step 240 may be an aggressive, high pressure etch that etches almost all surface features evenly, namely blocking layer 238, metal layer 228, inter-metal dielectric, as well as any lining layers 226 are etched at a generally uniform rate by the first CMP process 240. This first CMP process 240 continues until a selected etch stop time. It may be a timed etch that will stop after a selected time period. Alternatively, it may be an end-of-point etch that is designed to stop upon reaching a selected feature, such as detecting the presence of the substrate material 125 as being etched, or some other end point indicating that the aggressive CMP is to be concluded, and a light CMP, (also referred to herein as a touch CMP), process is then to be carried out. As mentioned, the second CMP process may have a chemical composition which is different from the first, which is not as aggressive in etching the metal layer 228. Therefore, during the second CMP step, removal of the metal layer 228 is predominantly carried out by the polishing aspect of the CMP process rather than by the chemical aspect of the CMP process. A final planar surface 246 is thus achieved without much, if any, chemical etching of the metal layer 228. Because the metal fields 228 are only polished, and not subject to chemical removal, the gouges 117 and associated puddle defects are prevented. The diagram in FIG. 4C shows a dashed line 235 in which the first CMP process is terminated according to one embodiment. Namely, in this embodiment the metal contacts in the narrow trenches 117 have been fully exposed. However, the metal in the intermediate trench 224 or the wide trench 119 has yet to be exposed. In one embodiment, the first CMP etching 240 can continue for some distance after the first exposure of the narrow trenches 117, for example until the removal of some of the additional blocking material 238 that is over the medium and wide trenches 224 and 119, respectively. At some point, as illustrated by dashed line 237 in FIG. 4C, the first etching is concluded and a second CMP etching takes place. While the line 237 is shown as being just after the metal intermediate trench 224 is encountered, the first etching step can in fact stop earlier, prior to reaching the line 237. After this, a polish is carried out, as previously described as the touch polish or the light polish, which has very low abrasive characteristics both from a chemical and a mechanical standpoint, as shown in step 242.

After step 242 is completed, a further etch 244 is performed in order to remove all the portions of the blocking layer 238 which may remain. The light touch CMP process may continue until line 239, which may etch some into the metal layer 228 inside of the trench 224, reducing the height 234. When the etching process reaches approximately line 239, shown in FIG. 4C, the CMP process is concluded, and this is followed by the removal of the remnants of the blocking layer in step 244. Preferably, this is a wet etch which is highly selective to the blocking layer 238 and does not etch the metal layer 228. This final etch can remove stringers, debris, or other material from the upper metal surface to ensure that it is fully exposed for later contact. The result may be a slight dip in the center of extremely wide trenches 119 because the final etch 239 did not reach the very top metal layer. In some embodiments, the etch 242 is carried out until the line 239 is right at the topmost expected location of the metal height 236 in the widest trench 119. Thus, there will be little or no blocking material 238 on the topmost layer of the metal 228 in the trench 119 to be removed. Alternatively, there may be a small amount in such a layer which is removed and leaves a small dip in the very center. Such a small dip is very slight and significantly less than the dishing that would exist without the use of the blocking layer, and in which a multistep CMP process is carried out.

The use of a multistep CMP process is not required, according to one embodiment of the invention. In one embodiment, a CMP process is selected which is preferentially selective to the blocking layer 238 from the chemistry standpoint, and performs little to no etching from a chemical interaction standpoint of the metal layer 228. This can be a single etch step which is carried out in a somewhat aggressive fashion against the blocking layer 238 and also any other layers that are exposed with respect to a polishing standpoint, although from a chemical standpoint only a layer 238 is attacked chemically, and the remainder are etched away mainly by the mechanical polishing process. This process therefore would not cause a dishing effect in the metal layer 228 inside the wide trench 119, even if carried out as the only CMP etch until all etching is completed. In one embodiment, this single CMP etch continues until past the height 236 in which the metal layer 228 in the widest trench 119 is exposed. In such situations it is not necessary to perform the final wet etch in step 244 for removing the blocking layer with a wet chemical etch.

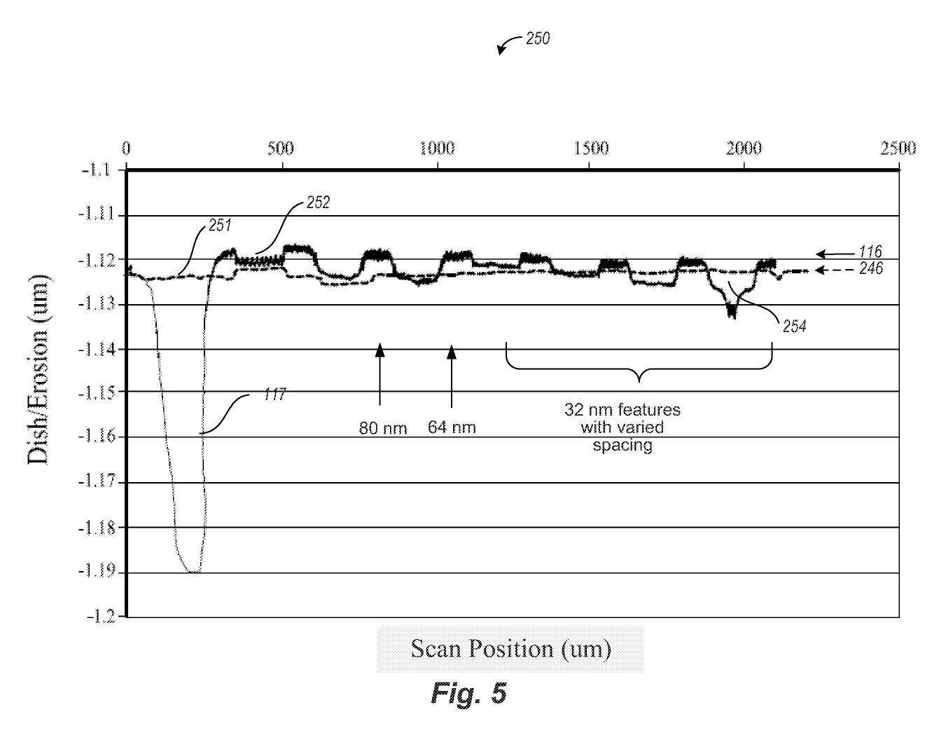

FIG. 5 shows a plot of vertical surface profiles 250 of the final planar surface 246 compared with a prior art non-planar surface such as that shown in FIG. 1 of the non-planar surface 116. Line 116 represents the surface profile of the prior art without this invention, and line 246 illustrates a surface profile with this invention. The vertical surface profiles 250 are derived from empirical data measured using atomic force microscopy (AFM). The deep gouge 117 corresponds to a metal field 112 in the form of a 150 pm wide copper pad, as shown in FIG. 1. Adjacent to the deep gouge 117, the surface profile 116 of a 150 μm wide SiCOH pad 252 is somewhat more uniform, demonstrating that dishing/erosion is particularly severe when the trench fill material 128 is metal. A second, shallower gouge 254 occurs for a 32 nm wide line pad. Overall, the non-planar surface profile 116 generally varies by about 7-8 nm. On the other hand, the final planar surface profile 246 varies by about 1-2 nm. As can be seen, the surface profile 246 is generally uniform across the entire width of the surface, to within about 5%. At the same location that the deep gouge 117 was formed in the prior art, the relatively flat, uniform surface profile 246 is formed in the layer in which the inventive steps have been carried out. There is a subsequent high spot immediately adjacent to somewhat low spot 251, as shown in the graph, and there are a few other locations in which there are minor variations in the topography of the top layer. However, as can be seen, the overall final layer is significantly smoother and more uniform in height than was possible in the prior art. Thus, in addition to eliminating the severe dishing and erosion of the metal fields 112 (e.g., the gouges 117 and 254), the uniform CMP method described herein also improves overall surface uniformity.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

It will be appreciated that, although specific embodiments of the present disclosure are described herein for purposes of illustration, various modifications may be made without departing from the spirit and scope of the present disclosure. Accordingly, the present disclosure is not limited except as by the appended claims.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of planarizing a surface, the method comprising:
forming a non-uniform pattern of trenches in a substrate;
partially filling the trenches with a fill material to create an irregular surface in which the fill material varies in thickness according to changes in pattern density of the non-uniform pattern;
depositing a conformal blocking layer over the irregular surface; and
performing a planarization process that avoids polishing a thinnest area of the irregular surface.

2. The method of claim 1, wherein the planarization process includes:
partially removing the blocking layer to expose fill material at a thickest area of the irregular surface;
polishing the exposed fill material; and
removing remnants of the blocking layer.

3. The method of claim 1 wherein the fill material includes one or more of copper, aluminum, tungsten, silver, gold, titanium, platinum, tantalum, or combinations thereof.

4. The method of claim 2 wherein the thickest area of the irregular surface corresponds to densely patterned regions.

5. The method of claim 1 wherein the filling the trenches includes electroplating.

6. The method of claim 1 wherein the filling the trenches includes electroless plating.

7. The method of claim 1 wherein the filling the trenches includes depositing metal by one or more of chemical vapor deposition (CVD) or plasma vapor deposition (PVD) processes.

8. The method of claim 1 wherein the blocking layer is made of a silicon carbide-nitride compound (SiCₓN_{y}).

9. The method of claim 2 wherein the removing remnants of the blocking layer entails performing a touch CMP process.

10. The method of claim 1 wherein depositing a conformal blocking layer over the irregular surface entails depositing an insulating material.

11. The method of claim 1 further comprising forming the non-uniform pattern of trenches in the substrate.

12. A planar damascene structure that includes features of disparate size, the structure comprising:
metal nanowires inlaid in an insulating material; and
metal fields inlaid in the insulating material, at least some of the metal fields being adjacent to some of the metal nanowires, an overall surface height of the planar damascene structure varying less than about 5%.

13. The planar damascene structure of claim 14 wherein the metal fields are about ten times wider than the metal nanowires.

14. The planar damascene structure of claim 13 wherein the metal nanowires have a width and spacing within a range of about 10 nm-100 μm and the metal fields have a width within a range of about 10 nm-100 μm.

15. The planar damascene structure of claim 12 wherein the metals of the metal nanowires and metal fields include one or more of copper, gold, silver, titanium, aluminum, tungsten, platinum, or combinations thereof.

16. A means of uniformly planarizing inlaid features of an integrated circuit, the features having disparate surface areas comprising:
means for creating inlaid features having disparate surface areas, the inlaid features being adjacent to one another;
means for covering a pattern of the inlaid features;
means for exposing the inlaid features having a smallest surface area, while the inlaid features having a largest surface area remain covered by a blocking layer;
means for removing a portion of the inlaid features having the smallest surface area; and
means for removing residual portions of the blocking layer from the inlaid features having the largest surface area.

17. The means of claim 16 wherein the inlaid features include an array of metal features inlaid in an electrically insulating material.

18. The means of claim 17 wherein the metal features are copper features.

19. The means of claim 17 wherein the array of metal features forms a damascene structure of the integrated circuit.

20. The means of claim 16 wherein the means for removing include a chemical-mechanical planarization (CMP) process.
